(19) United States
(12) Patent Application Publication
(10) Pub. No.: US 2022/0392832 A1
(43) Pub. Date: Dec. 8, 2022

(54) SEMICONDUCTOR STRUCTURES AND METHODS OF FORMING THE SAME

(71) Applicant: Taiwan Semiconductor Manufacturing Company, Ltd., Hsinchu (TW)

(72) Inventors: Wei-Yu Chen, Hsinchu City (TW); Yu-Min Liang, Taoyuan City (TW); Tsung-Ding Wang, Tainan (TW); Jiun-Yi Wu, Taoyuan City (TW); Chien-Hsun Lee, Hsin-chu County (TW)

(73) Assignee: Taiwan Semiconductor Manufacturing Company, Ltd., Hsinchu (TW)

(21) Appl. No.: 17/340,069

(22) Filed: Jun. 6, 2021

(51) Int. Cl. H01L 23/498; H01L 23/15; H01L 21/48; H01L 23/00

(52) U.S. Cl. CPC H01L 23/49822; H01L 23/15; H01L 23/49816; H01L 21/4857; H01L 21/486; H01L 24/81; H01L 24/16; H01L 2224/16227; H01L 24/32; H01L 2224/32225; H01L 24/73; H01L 2224/73204; H01L 2924/3511

(57) ABSTRACT

A method of forming a semiconductor structure includes the following operations. A first conductive structure is formed on a first side of a first glass carrier. A second glass carrier is bonded to the first conductive structure. Conductive vias are formed to penetrate through the first glass carrier, and the conductive vias are electrically connected to the first conductive structure. A second conductive structure is formed on a second side of the first glass carrier opposite to the first side, and the second conductive structure is electrically connected to the conductive vias.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area.

In some applications, integrated circuit components or semiconductor chips, one or more chip packages are generally bonded to a circuit board for electrical connections to other external devices or electronic components. Although the existing circuit board has been generally adequate for their intended purposes, it has not been entirely satisfactory in all respects.

### BRIEF DESCRIPTION OF THE DRAWINGS

FIG. 1 to FIG. 12 are cross-sectional views schematically illustrating a method of forming a semiconductor structure in accordance with some embodiments of the present disclosure.

FIG. 13 is a cross-sectional view schematically illustrating a semiconductor structure in accordance with other embodiments of the present disclosure.

FIG. 14 illustrates a method of forming a semiconductor structure in accordance with some embodiments of the present disclosure.

FIG. 15 illustrates a method of forming a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below for the purposes of conveying the present disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same reference numerals and/or letters may be used to refer to the same or similar parts in the various examples the present disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

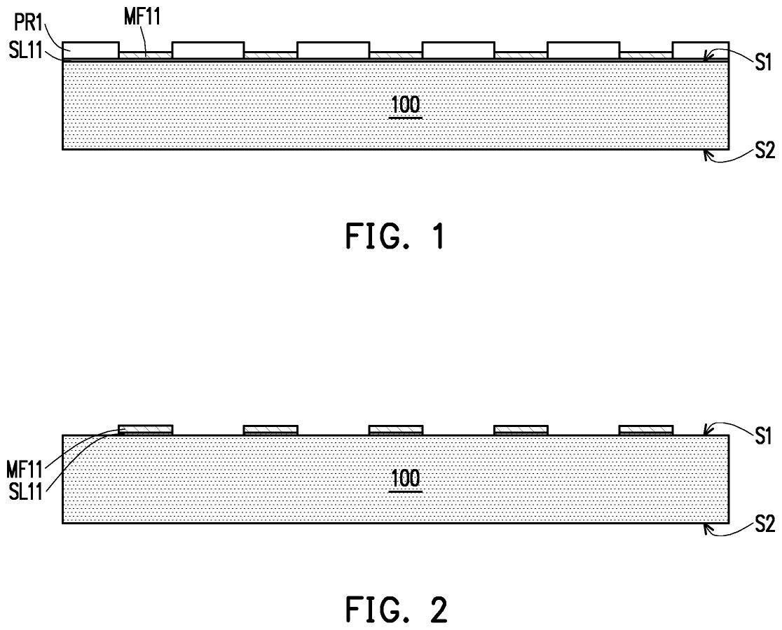

FIG. 1 to FIG. 12 are cross-sectional views schematically illustrating a method of forming a semiconductor structure in accordance with some embodiments of the present disclosure. It is understood that the disclosure is not limited by the method described below. Additional operations can be provided before, during, and/or after the method and some of the operations described below can be replaced or eliminated, for additional embodiments of the methods.

Although FIG. 1 to FIG. 12 are described in relation to a method, it is appreciated that the structures disclosed in FIG. 1 to FIG. 12 are not limited to such a method, but instead may stand alone as structures independent of the method.

Referring to FIG. 1, a seed layer SL11 is formed on a glass carrier 100. In some embodiments, the glass carrier 100 has a first side S1 and a second side S2 opposite to the first side S1. The glass carrier is referred to as a “glass core layer”, “blank glass layer” or “glass support” in some examples. In some embodiments, the seed layer SL11 is formed on the entire surface of the first side S1 of the glass carrier 100 and is formed by a sputtering process or a suitable method. In some embodiments, the seed layer SL11 includes Cu, Ti, Ta, W, Ru, Co, Ni. Au or an alloy thereof. For example, the seed layer SL11 includes Ti/Cu; that is, a lower Ti layer and an upper Cu layer.

Thereafter, a photoresist layer PR1 is formed on the seed layer SL11. In some embodiments, the photoresist layer PR1 is a dry film resist (DFR) over the glass carrier 100 and has openings that expose the intended locations for the subsequently formed metal features MF11. The openings of the photoresist layer PR1 expose portions of the seed layer SL11.

Thereafter, metal features MF11 are formed in the openings of the photoresist layer PR1. The metal features MF11 may be metal pads, metal lines or the like. In some embodiments, the method of forming the metal features MF11 includes performing an electroplating process. In some embodiments, the metal features MF11 are plated in the openings of the photoresist layer PR1 by using the seed layer SL11 as a seed. In some embodiments, the metal features MF11 include Cu, Ti, Ta, W, Ru, Co, Ni. Au or an alloy thereof. For example, the metal features MF11 include Cu.

Referring to FIG. 2, the photoresist layer PR1 and the underlying seed layer SL11 are removed. In some embodiments, the photoresist layer PR1 is removed, and then the seed layer SL11 is partially removed by using the metal features MF11 as a mask. Therefore, the remaining seed layer SL11 is below each of the metal features MF11. In some embodiments, the edge of the seed layer SL11 is aligned with the edge of the corresponding metal feature MF11. In other embodiments, the edge of the seed layer SL11 is protruded out from the edge of the corresponding metal feature MF11.

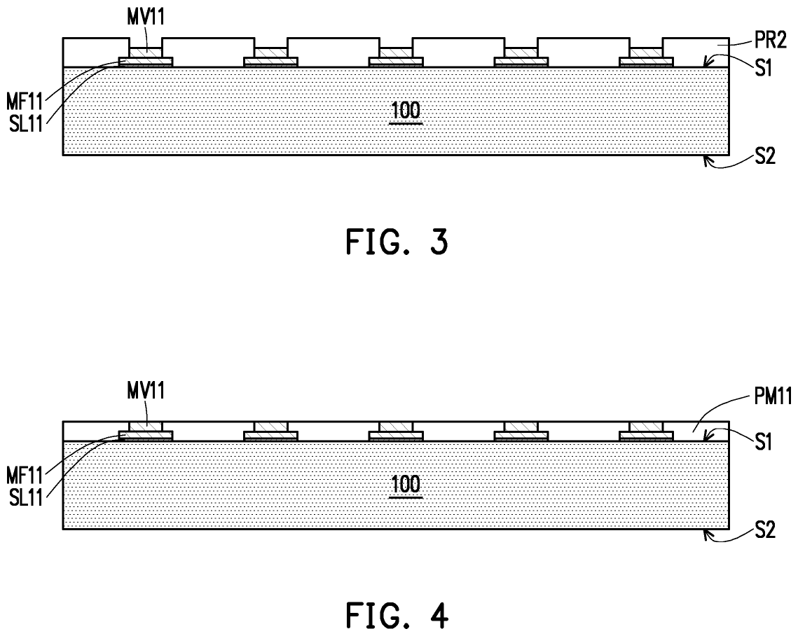

Referring to FIG. 3, a photoresist layer PR2 is formed on the first side S1 of the glass carrier 100. In some embodiments, the photoresist layer PR2 is a dry film resist (DFR) over the glass carrier 100 and has openings that expose the intended locations for the subsequently formed metal vias MV11. The openings of the photoresist layer PR2 expose portions of the metal features MF11.

Thereafter, the metal vias MV11 are formed in the openings of the photoresist layer PR2. In some embodiments, the method of forming the metal vias MV11 includes performing an electroplating process. In some embodiments, the metal vias MV11 are plated in the openings of the photoresist layer PR2 by using the metal features MF11 as a seed. In some embodiments, the metal vias MV11 include Cu, Ti, Ta, W, Ru, Co, Ni. Au or an alloy thereof. For example, the metal vias MV11 include Cu. The photoresist layer PR2 is then removed.

Referring to FIG. 4, a polymer layer PM11 is formed over the glass carrier 100 and surrounds the sidewalls of the seed layers SL11, the metal features MF11 and the metal vias MV11. In some embodiments, a polymer material is formed (e.g., laminated or coated) to cover the metal features MF11 and the metal vias MV11, and a planarization process (e.g., grinding or polishing process) is performed to remove a portion of the polymer material until the top surfaces of the metal vias MV11 are exposed. The top surface of the polymer layer PM11 is substantially coplanar with the top surfaces of the metal vias MV11. In some embodiments, the polymer layer PM11 includes a polymer material and filler particles. In some embodiments, the polymer material includes polybenzoxazole (PBO), polyimide (PI), benzocyclobutene (BCB), the like, or a combination thereof, and the filler particles include silica, alumina, zinc oxide, titanium dioxide, or the like. In some embodiments, the filler particles may be sphere-shaped or globular. In some embodiments, the content of the filler particles in the total of the polymer layer PM11 ranges from about 1 wt % to about 80 wt %, such as from about 1 wt % to about 50 wt %.

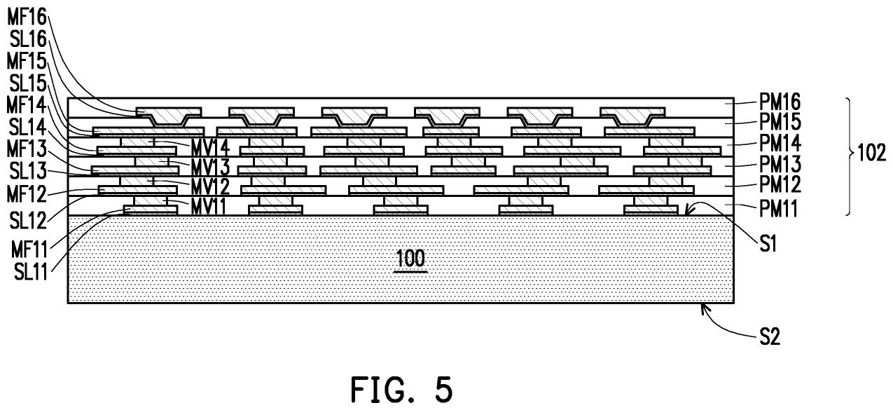

Referring to FIG. 5, the operations similar to those in FIG. 1 to FIG. 4 are performed, so as to form metal features MF12 electrically connected to the metal vias MV11, the metal vias MV12 electrically connected to the metal features MF12, and a polymer layer PM12 surrounding the metal features MF12 and the metal vias MV12. In some embodiments, a seed layer SL12 is formed between each metal feature MF12 and the underlying polymer layer PM11 and the metal via MV11. In some embodiments, the materials of the seed layers SL12, the metal features MF12, the metal vias MV12 and the polymer layer PM12 are similar those of the seed layers SL11, the metal features MF11, the metal vias MV11 and the polymer layer PM11, so the details are not iterated herein.

Thereafter, the operations similar to those in FIG. 1 to FIG. 4 are performed, so as to form metal features MF13 electrically connected to the metal vias MV12, the metal vias MV13 electrically connected to the metal features MF13, and a polymer layer PM13 surrounding the metal features MF13 and the metal vias MV13. In some embodiments, a seed layer SL13 is formed between each metal feature MF13 and the underlying polymer layer PM12 and between each metal feature MF13 and the underlying metal via MV12. In some embodiments, the materials of the seed layers SL13, the metal features MF13, the metal vias MV13 and the polymer layer PM13 are similar those of the seed layers SL11, the metal features MF11, the metal vias MV11 and the polymer layer PM11, so the details are not iterated herein.

Afterwards, the operations similar to those in FIG. 1 to FIG. 4 are performed, so as to form metal features MF14 electrically connected to the metal vias MV13, the metal vias MV14 electrically connected to the metal features MF14, and a polymer layer PM14 surrounding the metal features MF14 and the metal vias MV14. In some embodiments, a seed layer SL14 is formed between each metal feature MF14 and the underlying polymer layer PM13 and between each metal feature MF14 and the underlying metal via MV13. In some embodiments, the materials of the seed layers SL14, the metal features MF14, the metal vias MV14 and the polymer layer PM14 are similar those of the seed layers SL11, the metal features MF11, the metal vias MV11 and the polymer layer PM11, so the details are not iterated herein.

Next, metal features MF15 are formed to electrically connect to the metal vias MV14, and a polymer layer PM15 is formed to cover the metal features MF15. In some embodiments, a seed layer SL15 is formed between each metal feature MF15 and the underlying polymer layer PM14 and between each metal feature MF15 and the underlying metal via MV14. In some embodiments, the materials of the seed layers SL15, the metal features MF15 and the polymer layer PM15 are similar those of the seed layers SL11, the metal features MF11 and the polymer layer PM11, so the details are not iterated herein.

Thereafter, metal features MF16 (e.g., under bump metallization pads) are formed to penetrate through the polymer layer PM15, and electrically connected to the metal features MF15. In some embodiments, a seed layer SL16 is formed between each metal feature MF16 (e.g., UBM pad) and the underlying metal feature MF15 and each metal feature MF16 (e.g., UBM pad) and the underlying polymer layer PM15. Afterwards, a polymer layer PM16 is formed to cover the metal features MF16. In some embodiments, a conductive structure 102 of this embodiment is thus completed, in which the metal features MF16 are the outermost metal features for ball mount, and the polymer layer PM16 is the outermost polymer layer serving as a buffer layer or protection layer. In some embodiments, the materials of the seed layers SL16, the metal features MF16 and the polymer layer PM16 are similar those of the seed layers SL11, the metal features MF11 and the polymer layer PM11, but the composition of the polymer layer PM16 is different from that of the polymer layer PM11. Specifically, the polymer layer PM16 and the polymer layer PM11 may have the same material but different compositions. In some embodiments, the polymer layer PM16 includes a polymer material and optional filler particles. In some embodiments, the polymer material includes polybenzoxazole (PBO), polyimide (PI), benzocyclobutene (BCB), the like, or a combination thereof, and the filler particles include silica, alumina, zinc oxide, titanium dioxide, or the like. In some embodiments, the filler particles may be sphere-shaped or globular. In some embodiments, the content of the filler particles in the total of the polymer layer PM11 ranges from about 0 wt % to about 20 wt %, such as from about 0 wt % to about 10 wt %.

The polymer layer PM16 is formed softer than the underlying polymer layers and serves as a buffer layer or a protection layer. Specifically, the species of the filler particles between the outermost polymer layer PM16 and the underlying polymer layer may be the same or different, but the amount of the filler particles in the outermost polymer layer PM16 is less than the amount of the filler particles in the underlying polymer layer. In some embodiments, the outermost polymer layer PM16 is a filler-free polymer layer. In some embodiments, the coefficient of thermal expansion (CTE) of the polymer layer PM16 is different from (e.g. higher than) the CTE of the underlying polymer layer, so as to balance the CTE and prevent warpage of the structure.

The layer number of the conductive structure 102 of the disclosure is not limited by the figures. The above operations may be repeated as many times as needed. The conductive structure 102 is referred to as a “wiring layer” or “build-up layer” in some examples.

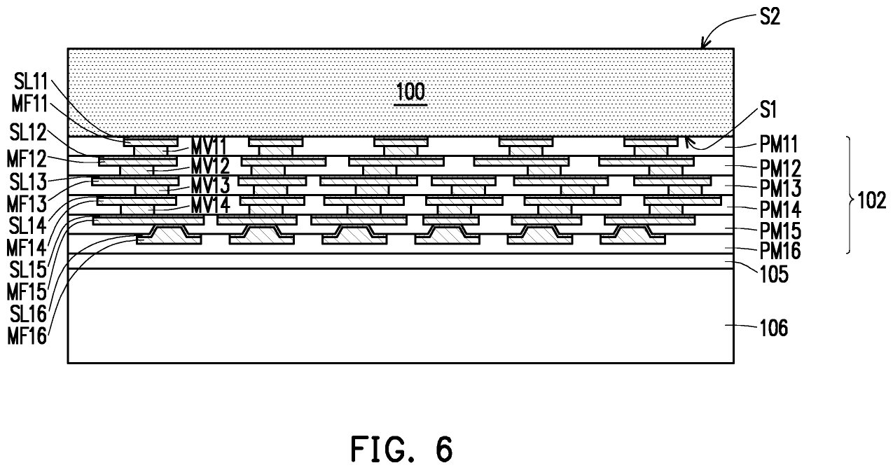

Referring to FIG. 6, the glass carrier 100 with the conductive structure 102 are turned over and bonded to a glass carrier 106. Specifically, the conductive structure 102 is bonded to the glass carrier 106 through a glue layer 105. In some embodiments, the outermost polymer layer PM16 of the conductive structure 102 faces the glass carrier 106 and is in contact with the glue layer 105. The glue layer 105 may be formed of an adhesive such as an Ultra-Violet (UV) glue, a Light-to-Heat Conversion (LTHC) glue, or the like, although other types of adhesives may be used. In some embodiments, the glue layer 105 is decomposable under the heat of light to thereby release the glass carrier 106 from the structure formed thereon. The glass carrier 106 is configured to support the intermediate structure and will be removed eventually, so other material may be used to replace the glass carrier 106. For example, a silicon carrier or a ceramic carrier may be applicable.

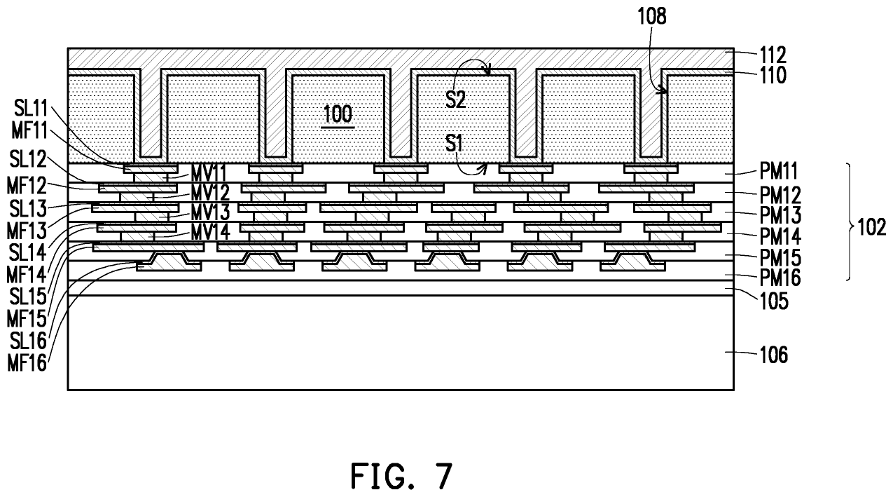

Referring to FIG. 7, through holes 108 are formed in the glass carrier 100. In some embodiments, a patterning process (e.g., a laser drilling, an etching or the like) is performed to the second side S2 of the glass carrier 100, so as to form the through holes 108 that penetrate through the glass carrier 100 and expose the underlying seed layers SL11. In some embodiments, portions of the seed layers SL11 are removed by the patterning process, so the through holes 108 expose top surfaces of the underlying metal features MF11 and sidewalls of the remaining seed layers SL11.

Thereafter, a seed layer 110 is formed conformally on the second side S2 of the glass carrier 100, covering the sidewalls and bottoms of the through holes 108. In some embodiments, the seed layer 110 is in physical contact with the underlying seed layers SL11 of the conductive structure 102. In some embodiments, the seed layer 110 is in physical contact with both the seed layers SL11 and the metal features MF11 of the conductive structure 102 when the through holes 108 extend into the surface portion of the conductive structure 102. In some embodiments, the seed layer 110 includes Cu, Ti, Ta, W, Ru, Co, Ni. Au or an alloy thereof, and is formed by a sputtering process or a suitable method. For example, the seed layer 110 includes Ti/Cu; that is, a lower Ti layer and an upper Cu layer.

Afterwards, a metal layer 112 is formed in the through holes 108 of the glass carrier 100. In some embodiments, the method of forming the metal layer 112 includes performing an electroplating process. In some embodiments, the metal layer 112 is plated in the through holes 108 of the glass carrier 100 by using the seed layer 110 as a seed. In some embodiments, the metal layer 112 includes Cu, Ti, Ta, W, Ru, Co, Ni. Au or an alloy thereof. For example, the metal layer 112 includes Cu.

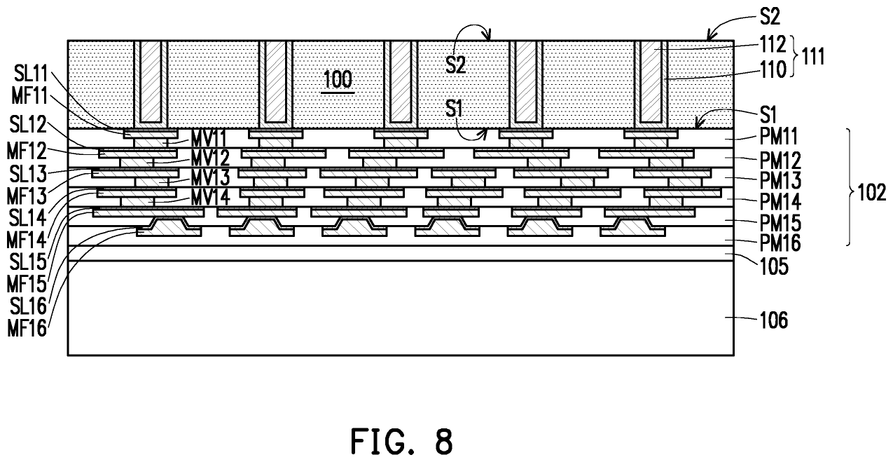

Referring to FIG. 8, a planarization process (e.g., grinding or polishing process) is performed to remove portions of the seed layer 110 and the metal layer 112 outside of the through holes 108. The remaining seed layer 110 and the metal layer 112 inside each of the through holes 108 constitute a conductive via 111. In some embodiments, the conductive vias 111 are referred to as “through vias” or “through glass vias (TGVs)” in some examples. The top surfaces of the seed layer 110 and the metal layer 112 are substantially coplanar with the second side S2 of the glass carrier 100.

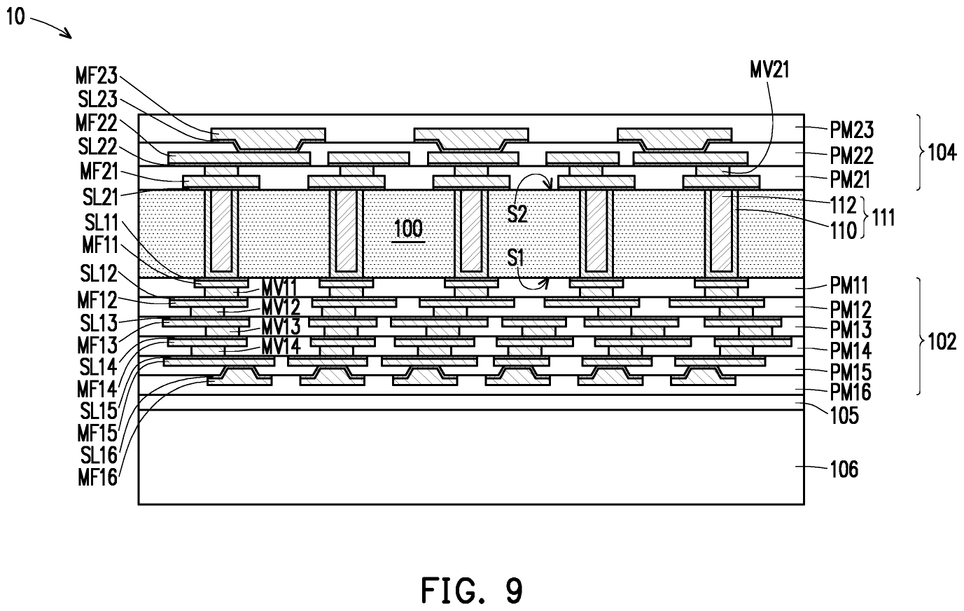

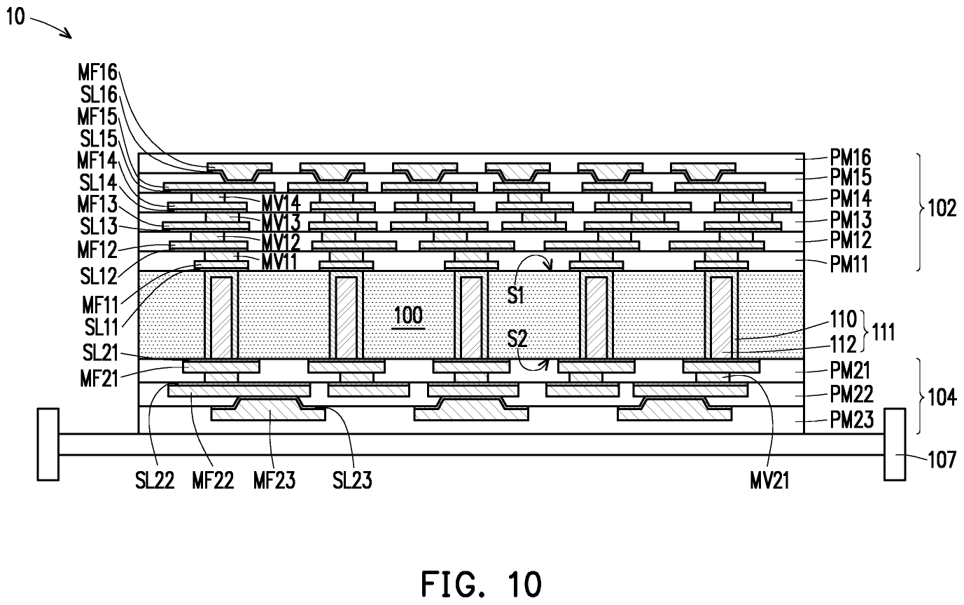

Referring to FIG. 9, a conductive structure 104 is formed on the second side S2 of the glass carrier 100 and electrically connected to the conductive vias 111. The method of forming the conductive structure 104 is similar to the method of forming the conductive structure 102.

In some embodiments, the operations similar to those in FIG. 1 to FIG. 4 are performed, so as to form metal features MF21 electrically connected to the conductive vias 111, metal vias MV21 electrically connected to the metal features MF21, and a polymer layer PM21 surrounding the metal features MF21 and the metal vias MV21. In some embodiments, a seed layer SL21 is formed between each metal feature MF21 and the underlying glass carrier 100 and between each metal feature MF21 and the underlying conductive via 111. In some embodiments, the edge of the seed layer SL21 is aligned with the edge of the corresponding metal feature MF21. In other embodiments, the edge of the seed layer SL21 is protruded out from the edge of the corresponding metal feature MF21.

In some embodiments, each of the seed layers SL21, the metal features MF21 and the metal vias MV21 includes Cu, Ti, Ta, W, Ru, Co, Ni. Au or an alloy thereof. For example, the seed layers SL21 include Ti/Cu, the metal features MF21 include Cu, and the metal vias MV21 include Cu. In some embodiments, the polymer layer PM21 includes a polymer material and filler particles. In some embodiments, the polymer material includes polybenzoxazole (PBO), polyimide (PI), benzocyclobutene (BCB), the like, or a combination thereof, and the filler particles include silica, alumina, zinc oxide, titanium dioxide, or the like. In some embodiments, the filler particles may be sphere-shaped or globular. In some embodiments, the content of the filler particles in the total of the polymer layer PM21 ranges from about 1 wt % to about 80 wt %, such as from about 1 wt % to about 50 wt %.

Thereafter, metal features MF22 are formed to electrically connect to the metal vias MV21, and a polymer layer PM22 is formed to cover the metal features MF22. In some embodiments, a seed layer SL22 is formed between each metal feature MF22 and the underlying polymer layer PM21 and between each metal feature MF22 and the underlying metal via MV21. In some embodiments, the materials of the seed layers SL22, the metal features MF22 and the polymer layer PM22 are similar those of the seed layers SL21, the metal features MF21 and the polymer layer PM21, so the details are not iterated herein.

Thereafter, metal features MF23 (e.g., under bump metallization pads) are formed to penetrate through the polymer layer PM22, and electrically connected to the metal features MF22. In some embodiments, a seed layer SL23 is formed between each metal feature MF23 (e.g., UBM pad) and the underlying metal feature MF22 and between each metal feature MF23 (e.g., UBM pad) and the underlying polymer layer PM22. Afterwards, a polymer layer PM23 is formed to cover the metal features MF23. In some embodiments, a conductive structure 104 of this embodiment is thus completed, in which the metal features MF23 are the outermost metal features for ball mount, and the polymer layer PM23 is the outermost polymer layer serving as a buffer layer or protection layer. In some embodiments, the materials of the seed layers SL23, the metal features MF23 and the polymer layer PM23 are similar those of the seed layers SL21, the metal features MF21 and the polymer layer PM21, but the composition of the polymer layer PM23 is different from that of the polymer layer PM21. Specifically, the polymer layer PM23 and the polymer layer PM21 may have the same material but different compositions. In some embodiments, the polymer layer PM23 includes a polymer material and optional filler particles. In some embodiments, the polymer material includes polybenzoxazole (PBO), polyimide (PI), benzocyclobutene (BCB), the like, or a combination thereof, and the filler particles include silica, alumina, zinc oxide, titanium dioxide, or the like. In some embodiments, the filler particles may be sphere-shaped or globular. In some embodiments, the content of the filler particles in the total of the polymer layer PM23 ranges from about 0 wt % to about 20 wt %, such as from about 0 wt % to about 10 wt %.

The polymer layer PM23 is formed softer than the underlying polymer layers and serves as a buffer layer or a protection layer. Specifically, the species of the filler particles between the outermost polymer layer PM23 and the underlying polymer layer may be the same or different, but the amount of the filler particles in the outermost polymer layer PM23 is less than the amount of the filler particles in the underlying polymer layer. In some embodiments, the outermost polymer layer PM23 is a filler-free polymer layer. In some embodiments, the CTE of the polymer layer PM23 is different from (e.g. higher than) the CTE of the underlying polymer layers, so as to balance the CTE and prevent warpage of the structure.

The layer number of the conductive structure 104 of the disclosure is not limited by the figures. The above operations may be repeated as many times as needed. The conductive structure 104 is referred to as a “wiring layer” or “build-up layer” in some examples.

In some embodiments, the dimension of the conductive structure 104 is different from (e.g., greater than) the dimension of the conductive structure 102. In some embodiments, the dimension includes a width, a height or a critical dimension (e.g., the smallest dimension) of the metal features of the conductive structure.

In some embodiments, the glass carrier 100, the conductive structure 102 and the conductive structure 104 constitute a glass substrate 10, in which the conductive structure 102 and the conductive structure 104 are electrically connected to each other through the conductive vias 111 in the glass carrier 100. The glass substrate 10 is referred to as a “glass circuit board” or “integrated glass substrate” in some examples.

Referring to FIG. 10, the glass carrier 100 with the conductive structures 102 and 104 are turned over and bonded to a frame 107. Specifically, the conductive structure 104 is bonded to the frame 107. In some embodiments, the outermost polymer layer PM23 of the conductive structure 104 faces the frame 107.

Thereafter, the glass carrier 106 is removed from the conductive structure 102. In some embodiments, the glue layer 105 is decomposed under heat of light, and the glass carrier 106 is then released from the conductive structure 102.

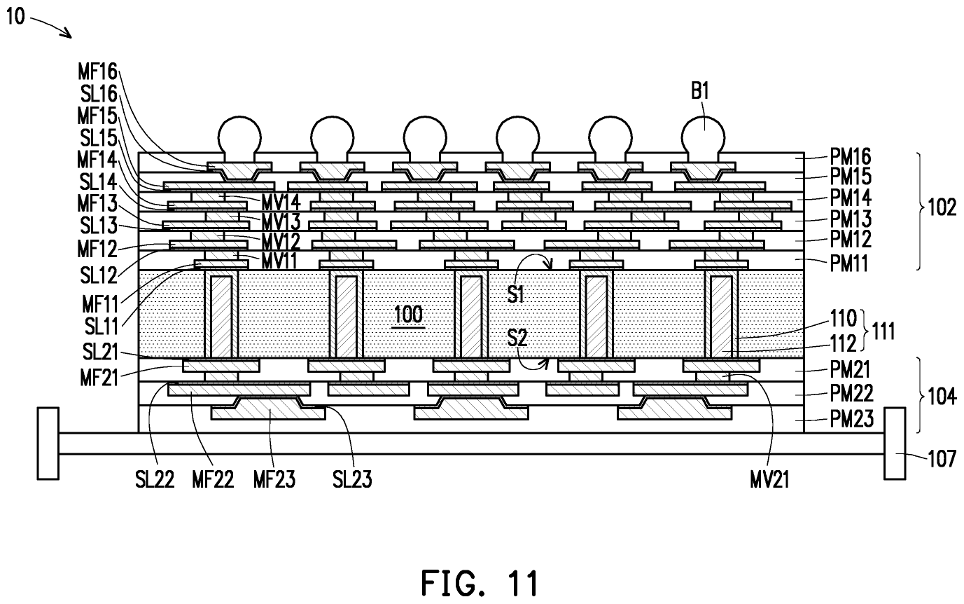

Referring to FIG. 11, conductive terminals or bumps B1 are formed to electrically connect to the conductive structure 102. In some embodiments, a patterning process (e.g., a laser drilling, an etching or the like) is performed to the polymer layer PM16, such that openings are formed in the polymer layer PM16 and expose the metal features MF16 (e.g., UBM pads). Thereafter, bumps B1 are formed within the openings of the polymer layer PM16 and electrically connected to the metal features MF16. In some embodiments, the bumps B1 include solder bumps, and/or may include metal pillars (e.g., copper pillars), solder caps formed on metal pillars, and/or the like. The bumps B1 may be formed by a suitable process such as evaporation, electroplating, ball drop, or screen printing. The bumps B1 are regarded as part of glass substrate 10 in some examples. In some embodiments, after the ball placement, a singulation process is performed to separate the wafer-type glass substrate into multiple chiplet-type glass substrates.

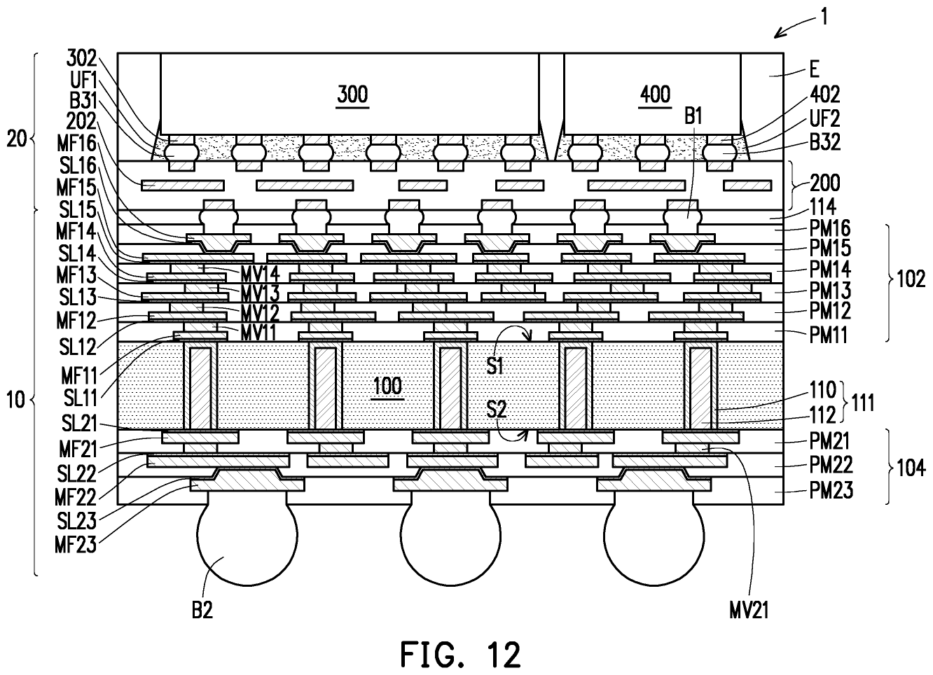

Referring to FIG. 12, a semiconductor package 20 is provided and bonded to the conductive structure 102 of the glass substrate 10 through the bumps B1. In some embodiments, an underfill layer 114 is provided between the glass substrate 10 and the semiconductor package 20 and around the bumps B1. The underfill layer 114 includes a molding compound such as epoxy, and is formed using dispensing, injecting, and/or spraying process.

In some embodiments, the semiconductor package 20 includes two dies 300 and 400 and an interposer 200 electrically connected to the dies 300 and 400. In some embodiments, each of the dies 300 and 400 may be an application-specific integrated circuit (ASIC) chip, an analog chip, a sensor chip, a wireless and radio frequency chip, a voltage regulator chip or a memory chip. In some embodiments, each of the dies 300 and 400 may be substituted with a die stack including multiple dies stacked vertically. In some embodiments, each of the dies 300 and 400 may include an active component or a passive component. In some embodiments, one of the dies 300 and 400 may be a device-free dummy die. In some embodiments, the dies 300 and 400 may have different sizes and functions. In some embodiments, the dies 300 and 400 include die pads 302 and 402, respectively.

The interposer 200 provides electrical routing between the dies 300 and 400. In some embodiments, the interposer 200 includes wiring patterns 202 therein. In some embodiments, each wring pattern 102 includes Cu, Al, Ti, Ta, W, Ru, Co, Ni, the like, or a combination thereof. In some embodiments, the interposer 200 is a silicon interposer, and the wiring patterns 202 include metal lines, metal vias and metal pads electrically connected to each other and embedded by dielectric materials and further include through silicon vias embedded by a silicon substrate. In other embodiments, the interposer 200 is an organic interposer, and the wiring patterns 202 include metal lines, metal vias and metal pads electrically connected to each other and embedded by organic materials.

In some embodiments, the die 300 is bonded to the interposer 200 through conductive terminals or bumps B31, and the die 400 is bonded to the interposer 200 through conductive terminals or bumps B32. The bumps B31 and B32 include solder bumps, and/or may include metal pillars (e.g., copper pillars), solder caps formed on metal pillars, and/or the like.

In some embodiments, underfill layers UF1 and UF2 are further included in the semiconductor package 20. The underfill layer UF1 is formed to fill the space between the die 300 and the interposer 200, and surrounds the bumps B31. The underfill layer UF2 is formed to fill the space between the die 400 and the interposer 200, and surrounds the bumps B32. In some embodiments, each of the underfill layers UF1 and UF2 includes a molding compound such as epoxy, and is formed using dispensing, injecting, and/or spraying process. In some embodiments, the underfill layers UF1 and UF2 are spaced from each other. In some embodiments, an underfill dissipation block may be provided on the interposer 200 between the dies 300 and 400, so as to prevent the underfill layers UF1 and UF2 from bleeding to undesired components. However, the disclosure is not limited thereto. In some embodiments, the underfill layers UF1 and UF2 are connected to each other.

In some embodiments, an encapsulation layer E is further included in the semiconductor package 20. The encapsulation layer E is formed to encapsulate the dies 300 and 400. In some embodiments, the encapsulation layer E includes a molding compound, epoxy, or the like, and may be applied by compression molding, transfer molding, or the like. The encapsulation layer E may be formed over the interposer substrate 200 and covering the dies 300 and 400. Thereafter, the encapsulation layer E may be optionally grinded, until top surfaces of the dies 300 and 400 are exposed.

Thereafter, the frame 107 is removed from the conductive structure 104, and conductive terminals or bumps B2 are formed to electrically connect to the conductive structure 104.

The bumps B2 are formed to electrically connect to the conductive structure 104. In some embodiments, a patterning process (e.g., a laser drilling, an etching or the like) is performed to the polymer layer PM23, such that openings are formed in the polymer layer PM23 and expose the metal features MF23 (e.g., UBM pads). Thereafter, bumps B2 are formed within the openings of the polymer layer PM23 and electrically connected to the metal features MF23. In some embodiments, the bumps B2 include solder bumps, and/or may include metal pillars (e.g., copper pillars), solder caps formed on metal pillars, and/or the like. The bumps B2 may be formed by a suitable process such as evaporation, electroplating, ball drop, or screen printing. The bumps B2 are regarded as part of glass substrate 10 in some examples. A semiconductor structure 1 including a glass substrate 10 and a semiconductor package 20 is thus completed.

The above embodiments in which the semiconductor package 20 is a chip-on-wafer (CoW) package are provided for illustration purpose, and are not construed as limited the present disclosure. In other embodiments, the semiconductor package is an integrated fan-out (InFO) package or other type of package.

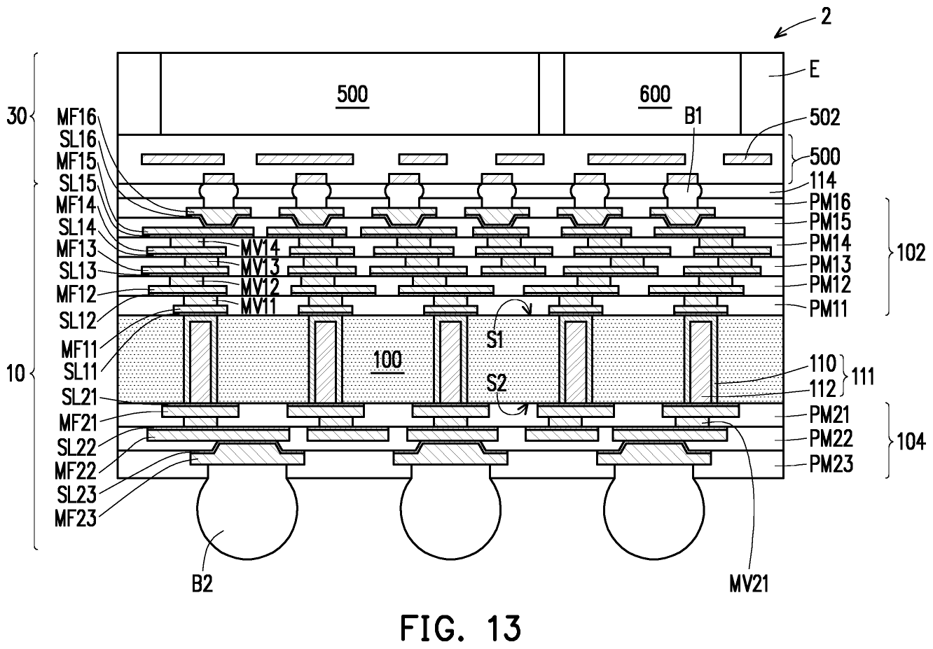

FIG. 13 is a cross-sectional view schematically illustrating a semiconductor structure in accordance with other embodiments of the present disclosure. The semiconductor structure 2 of FIG. 13 is similar to the semiconductor structure 1 of FIG. 12, and the difference between them lies in the types of the semiconductor packages.

Referring to FIG. 13, a semiconductor package 30 is provided and bonded to the conductive structure 102 of the glass substrate 10 through the bumps B1. In some embodiments, an underfill layer 114 is provided between the glass substrate 10 and the semiconductor package 30 and around the bumps B1. The underfill layer 114 includes a molding compound such as epoxy, and is formed using dispensing, injecting, and/or spraying process.

In some embodiments, the semiconductor package 30 includes two dies 500 and 600, and a redistribution layer structure 700 electrically connected to the dies 500 and 600. In some embodiments, each of the dies 500 and 600 may be an application-specific integrated circuit (ASIC) chip, an analog chip, a sensor chip, a wireless and radio frequency chip, a voltage regulator chip or a memory chip. In some embodiments, each of the dies 500 and 600 may be substituted with a die stack including multiple dies stacked vertically. In some embodiments, each of the dies 500 and 600 may include an active component or a passive component. In some embodiments, one of the dies 500 and 600 may be a device-free dummy die. In some embodiments, the dies 500 and 600 may have different sizes and functions.

In some embodiments, the redistribution layer structure 700 is formed directly on the dies 500 and 600, in which solder bumps are not present between the redistribution layer structure 700 and each of the dies 500 and 600. In some embodiments, the redistribution layer structure 700 includes redistribution patterns 702 therein. In some embodiments, each redistribution pattern 702 includes Cu, Al, Ti, Ta, W, Ru, Co, Ni, the like, or a combination thereof. In some embodiments, the redistribution patterns 702 include metal lines, metal vias and metal pads electrically connected to each other and embedded by dielectric materials. The redistribution layer structure 700 is formed by an electroplating process or a damascene process. In some embodiments, some redistribution patterns 702 of the redistribution layer structure 700 are in physical contact with the die pads of the dies 500 and 600.

In some embodiments, the disclosure provides an integrated glass substrate with low power loss, high electrical performance and adjustable CTE property. In the disclosure, smaller and finer metal features/vias are manufactured on the core glass material, so as to reduce the size of the integrated glass substrate. Besides, the integrated glass substrate of the disclosure is a process carrier and such configuration can simplify the process of system integrated substrate.

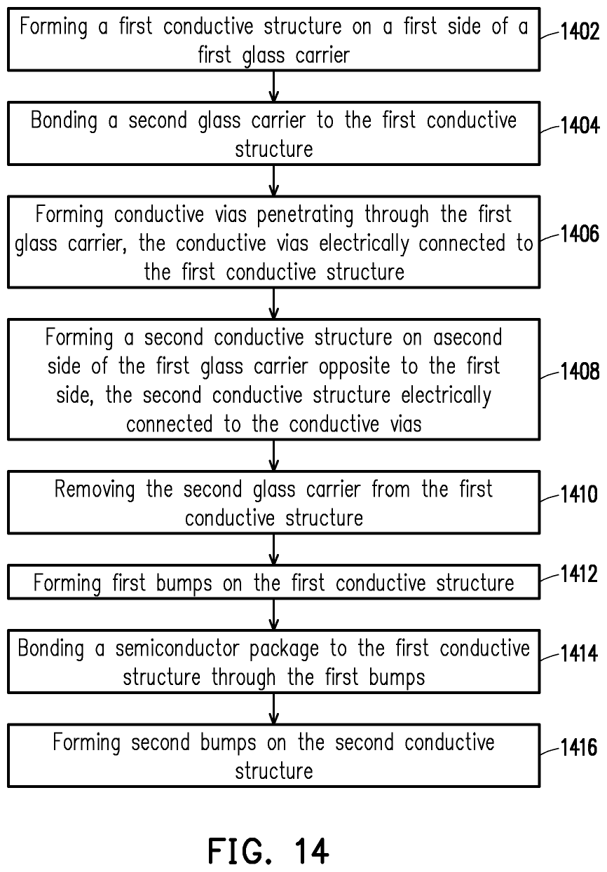

FIG. 14 illustrates a method of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1402, a first conductive structure is formed on a first side of a first glass carrier. In some embodiments, forming the first conductive structure includes forming a first seed layer on the first side of the first glass carrier, forming a first metal feature by using the first seed layer as a seed, and forming a first metal via by using the first metal feature as a seed. In some embodiments, the first conductive structure includes first metal features and first metal vias electrically connected to each other and embedded in first polymer layers, and a first polymer layer facing away from the first glass carrier is formed softer than a first polymer layer facing the first glass carrier. FIG. 1 to FIG. 5 illustrate cross-sectional views corresponding to some embodiments of act 1402.

At act 1404, a second glass carrier is bonded to the first conductive structure. FIG. 6 illustrates a cross-sectional view corresponding to some embodiments of act 1404.

At act 1406, conductive vias are formed to penetrate through the first glass carrier, and the conductive vias are electrically connected to the first conductive structure. In some embodiments, forming the conductive vias includes forming through holes in the first glass carrier, forming a seed layer conformally on sidewalls and bottoms of the through holes, and forming the conductive vias in the through holes by using the seed layer as a seed. FIG. 7 to FIG. 8 illustrate cross-sectional views corresponding to some embodiments of act 1406.

At act 1408, a second conductive structure is formed on a second side of the first glass carrier opposite to the first side, and the second conductive structure is electrically connected to the conductive vias. In some embodiments, forming the second conductive structure includes forming a second seed layer on the second side of the first glass carrier, forming a second metal feature by using the second seed layer as a seed, and forming a second metal via by using the second metal feature as a seed. In some embodiments, the second conductive structure includes second metal features and second metal vias electrically connected to each other and embedded in second polymer layers, and a second polymer layer facing away from the first glass carrier is formed softer than a second polymer layer facing the first glass carrier. FIG. 9 illustrates a cross-sectional view corresponding to some embodiments of act 1408.

At act 1410, the second glass carrier is removed from the first conductive structure. FIG. 10 illustrates a cross-sectional view corresponding to some embodiments of act 1410.

At act 1412, first bumps are formed on the first conductive structure. FIG. 11 illustrates a cross-sectional view corresponding to some embodiments of act 1412.

At act 1414, a semiconductor package is bonded to the first conductive structure through the first bumps. FIG. 12 to FIG. 13 illustrate cross-sectional views corresponding to some embodiments of act 1414.

At act 1416, second bumps are formed on the second conductive structure. FIG. 12 to FIG. 13 illustrate cross-sectional views corresponding to some embodiments of act 1416. The sequence of act 1414 and act 1416 may be exchanged as needed.

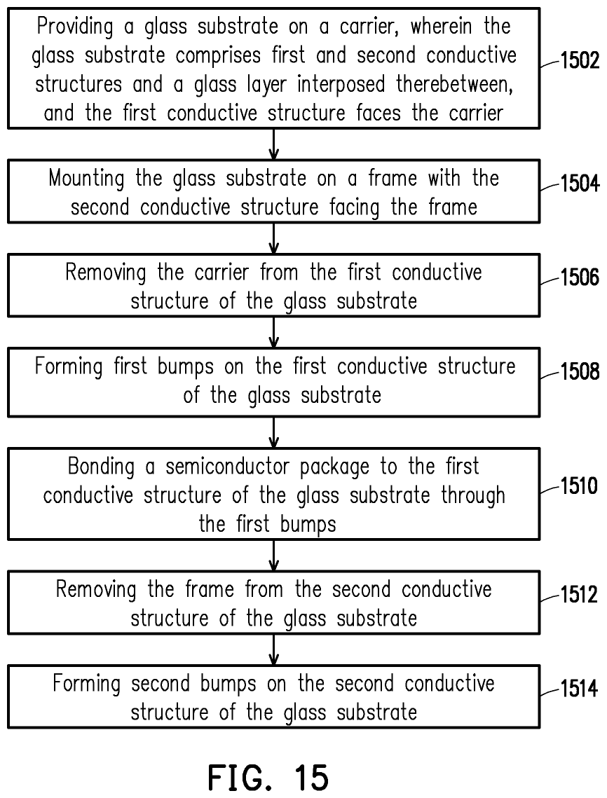

FIG. 15 illustrates a method of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1502, a glass substrate is provided on a carrier, wherein the glass substrate includes first and second conductive structures and a glass layer interposed therebetween, and the first conductive structure faces the carrier. In some embodiments, the first conductive structure is formed by an electroplating process. In some embodiments, the second conductive structure is formed by an electroplating process. In some embodiments, a critical dimension of the first conductive structure is less than a critical dimension of the second conductive structure. In some embodiments, the glass layer includes conductive vias that penetrate therethrough and are formed by an electroplating process. FIG. 1 to FIG. 9 illustrate cross-sectional views corresponding to some embodiments of act 1502.

At act 1504, the glass substrate is mounted on a frame with the second conductive structure facing the frame. FIG. 10 illustrates a cross-sectional view corresponding to some embodiments of act 1504.

At act 1506, the carrier is removed from the first conductive structure of the glass substrate. FIG. 10 illustrates a cross-sectional view corresponding to some embodiments of act 1506.

At act 1508, first bumps are formed on the first conductive structure of the glass substrate. FIG. 11 illustrates a cross-sectional view corresponding to some embodiments of act 1508.

At act 1510, a semiconductor package is bonded to the first conductive structure of the glass substrate through the first bumps. FIG. 12 to FIG. 13 illustrate cross-sectional views corresponding to some embodiments of act 1510.

At act 1512, the frame is removed from the second conductive structure of the glass substrate. FIG. 11 to FIG. 13 illustrate cross-sectional views corresponding to some embodiments of act 1512.

At act 1514, second bumps are formed on the second conductive structure of the glass substrate. FIG. 12 to FIG. 13 illustrate cross-sectional views corresponding to some embodiments of act 1514.

In the above embodiments, the critical dimension of the first conductive structure is less than the critical dimension of the second conductive structure, and the first conductive structure is formed prior to the formation of the second conductive structure. However, the disclosure is not limited thereto. In other embodiments, the first conductive structure with a smaller critical dimension may be formed after the formation of the second conductive structure with a greater critical dimension.

The structures of the disclosure are illustrated below with reference to FIG. 12 and FIG. 13. In some embodiments, a semiconductor structure 1/2 includes a glass substrate 10, first bumps B1 and second bumps B2. The glass substrate 10 includes a glass layer or a glass carrier 100, and first and second conductive structures 102 and 104 disposed on opposite sides of the glass layer 100 and electrically connected to each other through conductive vias 111 in the glass layer 100. In some embodiments, a critical dimension of the first conductive structure 102 is different from (e.g., less than) a critical dimension of the second conductive structure 104. The first bumps B1 are electrically connected to the first conductive structure 102 of the glass substrate 10. The second bumps B2 are electrically connected to the second conductive structure 104 of the glass substrate 10.

In some embodiments, each of the conductive vias 111 includes a metal layer 112 and a seed layer 110 surrounding a sidewall and a bottom of the metal layer 112. Specifically, in each of the conductive vias 111, the seed layer 110 is a U-shaped seed layer, and the metal layer 112 is a straight-shaped or I-shaped metal layer.

In some embodiments, the first conductive structure 102 includes a first seed layer SL11 and a first metal feature MF11, and the first seed layer SL11 is disposed between and in contact with one conductive via 111 and the first metal feature MF11.

In some embodiments, the second conductive structure 104 includes a second seed layer SL21 and a second metal feature MF21, and the second seed layer SL21 is disposed between and in contact with one conductive via 111 and the second metal feature MF21.

In some embodiments, the semiconductor structure 1/2 further includes a semiconductor package 20/30 electrically connected to the first conductive structure 102 of the glass substrate 10 through the first bumps B1.

In some embodiments, the semiconductor package 20 includes at least one die 300/400 and an interposer 200 disposed between the at least one die 300/400 and the first conductive structure 102 of the glass substrate 10.

In some embodiments, the semiconductor package 30 includes at least one die 500/600 and a redistribution layer structure 700 disposed between the at least one chip 500/600 and the first conductive structure 102 of the glass substrate 10.

In view of the above, the integrated glass substrate of the disclosure can reduce yield loss of heterogeneous integration. Specifically, metal features and polymer layers can be directly formed on glass, so as to reduce the substrate joining process.

Besides, the integrated glass substrate of the disclosure can enhance performance of package. Specifically, glass is a material with lower power/insertion loss and high electrical performance as compared to the conventional silicon and organic core material.

Moreover, the integrated glass substrate of the disclosure provides adjustable CTE property for large size PKG. Specifically, the CTE of the integrated glass substrate of the disclosure can be adjusted to match PCB mother board and silicon die.

In addition, the integrated glass substrate of the disclosure is beneficial to reduce cost of system of integrated substrate. Specifically, there is no need to purchase an organic substrate from the vendor, so the production cost of the integrated glass substrate of the disclosure is very competitive.

In accordance with some embodiments of the present disclosure, a method of forming a semiconductor structure includes the following operations. A first conductive structure is formed on a first side of a first glass carrier. A second glass carrier is bonded to the first conductive structure. Conductive vias are formed to penetrate through the first glass carrier, and the conductive vias are electrically connected to the first conductive structure. A second conductive structure is formed on a second side of the first glass carrier opposite to the first side, and the second conductive structure is electrically connected to the conductive vias.

In accordance with alternative embodiments of the present disclosure, a method of forming a semiconductor structure includes the following operations. A glass substrate is provided on a carrier, wherein the glass substrate includes first and second conductive structures and a glass layer interposed therebetween, the first and second conductive structures are electrically connected to each other, and the first conductive structure faces the carrier. The glass substrate is mounted on a frame with the second conductive structure facing the frame. The carrier is removed from the first conductive structure of the glass substrate. A semiconductor package is bonded to the first conductive structure of the glass substrate.

In accordance with yet alternative embodiments of the present disclosure, a semiconductor structure includes a glass substrate, first bumps and second bumps. The glass substrate includes a glass layer, and first and second conductive structures disposed on opposite sides of the glass layer and electrically connected to each other through conductive vias in the glass layer. The first bumps are electrically connected to the first conductive structure of the glass substrate. The second bumps are electrically connected to the second conductive structure of the glass substrate.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a first conductive structure on a first side of a first glass carrier;
bonding a second glass carrier to the first conductive structure;
forming conductive vias penetrating through the first glass carrier, the conductive vias electrically connected to the first conductive structure; and
forming a second conductive structure on a second side of the first glass carrier opposite to the first side, the second conductive structure electrically connected to the conductive vias.

2. The method of claim 1, wherein forming the conductive vias comprises:
forming through holes in the first glass carrier;
forming a seed layer conformally on sidewalls and bottoms of the through holes; and
forming the conductive vias in the through holes by using the seed layer as a seed.

3. The method of claim 1, further comprising removing the second glass carrier from the first conductive structure.

4. The method of claim 3, further comprising:
forming first bumps on the first conductive structure; and
forming second bumps on the second conductive structure, wherein a dimension of the first bumps is different from a dimension of the second bumps.

5. The method of claim 1, wherein forming the first conductive structure comprises:
forming a first seed layer on the first side of the first glass carrier;
forming a first metal feature by using the first seed layer as a seed; and
forming a first metal via by using the first metal feature as a seed.

6. The method of claim 1, wherein forming the second conductive structure comprises:
forming a second seed layer on the second side of the first glass carrier;
forming a second metal feature by using the second seed layer as a seed; and
forming a second metal via by using the second metal feature as a seed.

7. The method of claim 1, wherein the first conductive structure comprises first metal features and first metal vias electrically connected to each other and embedded in first polymer layers, and a first polymer layer facing away from the first glass carrier is formed softer than a first polymer layer facing the first glass carrier.

8. The method of claim 1, wherein the second conductive structure comprises second metal features and second metal vias electrically connected to each other and embedded in second polymer layers, and a second polymer layer facing away from the first glass carrier is formed softer than a second polymer layer facing the first glass carrier.

9. A method of forming a semiconductor structure, comprising:
providing a glass substrate on a carrier, wherein the glass substrate comprises first and second conductive structures and a glass layer interposed therebetween, the first and second conductive structures are electrically connected to each other, and the first conductive structure faces the carrier;
mounting the glass substrate on a frame with the second conductive structure facing the frame;
removing the carrier from the first conductive structure of the glass substrate; and
bonding a semiconductor package to the first conductive structure of the glass substrate.

10. The method of claim 9, wherein the glass layer comprises conductive vias penetrating therethrough and formed by an electroplating process.

11. The method of claim 9, wherein the first conductive structure is formed by an electroplating process.

12. The method of claim 9, wherein the second conductive structure is formed by an electroplating process.

13. The method of claim 9, wherein a critical dimension of the first conductive structure is different from a critical dimension of the second conductive structure.

14. The method of claim 9, further comprising:
forming first bumps on the first conductive structure of the glass substrate, wherein the semiconductor package is bonded to the first conductive structure of the glass substrate through the first bumps;
removing the frame from the second conductive structure of the glass substrate; and
forming second bumps on the second conductive structure of the glass substrate.

15. A semiconductor structure, comprising:
a glass substrate, comprising:
a glass layer; and
first and second conductive structures disposed on opposite sides of the glass layer and electrically connected to each other through conductive vias in the glass layer;
first bumps electrically connected to the first conductive structure of the glass substrate; and
second bumps electrically connected to the second conductive structure of the glass substrate.

16. The semiconductor structure of claim 15, wherein each of the conductive vias comprises a metal layer and a seed layer surrounding a sidewall and a bottom of the metal layer.

17. The semiconductor structure of claim 15, wherein the first conductive structure comprises a first seed layer and a first metal feature, and the first seed layer is disposed between and in contact with one conductive via and the first metal feature.

18. The semiconductor structure of claim 15, wherein the second conductive structure comprises a second seed layer and a second metal feature, and the second seed layer is disposed between and in contact with one conductive via and the second metal feature.

19. The semiconductor structure of claim 15, further comprising a semiconductor package electrically connected to the first conductive structure of the glass substrate through the first bumps.

20. The semiconductor structure of claim 15, wherein a critical dimension of the first conductive structure is less than a critical dimension of the second conductive structure.
